(19) United States
(12) Patent Application Publication
(10) Pub. No.: US 2015/0144160 A1
(43) Pub. Date: May 28, 2015

(54) ETCHANT, PREPARATION THEREOF AND METHOD OF USING THE SAME IN THE CLEANING PROCESS

(71) Applicant: Beijing Sevenstar Electronics Co., Ltd., Beijing (CN)

(72) Inventors: Sally Ann Henry, Minneapolis, MN (US); Jintao Huang, Beijing (CN); Jia Ma, Beijing (CN); Yi Wu, Beijing (CN); Yujia Su, Beijing (CN)

(21) Appl. No.: 14/127,978

(22) PCT Filed: Mar. 27, 2013
(86) PCT No.: PCT/CN2013/073276

§ 371 Date: Dec. 20, 2013

(30) Foreign Application Priority Data
Dec. 13, 2012 (CN) 201210540299.0

(51) Int. Cl. C11D 7/04; H01L 21/02; C11D 11/00

(52) U.S. Cl. CPC C11D 7/04; C11D 11/0047; C11D 11/0023; C11D 11/0064; H01L 21/02057
USPC 134/27; 510/175; 510/109; 134/28

(57) ABSTRACT

The present invention provides an etchant which is a reaction product of sulfuric acid and ammonium persulfate, wherein the concentration of the ammonium persulfate is 1˜25%, the concentration of the sulfuric acid is 98%. The etchant is produced by adding the ammonium persulfate into the sulfuric acid at a temperature of 100 to 200 degree Celsius. According to the present invention, the ammonium persulfate substitute the conventional oxidizing agent of hydrogen peroxide. Since the ammonium persulfate is in a powder form, the operation becomes more convenient. Furthermore, since sulfuric acid is formed as a by-product instead of water, the etchant will not be diluted after being used for many times, which reduces the production cost.

### CROSS-REFERENCE TO RELATED APPLICATION

This application claims the priority benefit of International Patent Application Serial No. PCT/CN2013/073,276, filed Mar. 27, 2013, which is related to and claims the priority benefit of China patent application serial no. 201210540299.0 filed Dec. 13, 2012. The entirety of each of the above-mentioned patent applications is hereby incorporated by reference herein and made a part of this specification.

### FIELD OF THE INVENTION

The present invention relates to the field of semiconductor cleaning technology, more particularly to an etchant, the preparation of the etchant and the method of using the etchant in the cleaning process.

### BACKGROUND OF THE INVENTION

The organic residues on the wafer surface comprise photoresist, oil sludge from the processing apparatus, oil from the skin, fingerprints, dander as well as the particles suspended in the air. These organic residues are likely to foam a film on the wafer. When an oxide layer, which forms on the wafer surface by some oxidizing cleaning liquid in a cleaning process, is required to be removed through the HF solution, such film will insulate the HF solution and the oxide layer, which prevents the removal of the oxide layer and affect the subsequent processing step of depositing the dopants into the wafer or the photomask area. Therefore, the removal of the organic residues is of great importance in the semiconductor industry.

Generally, a compound containing 98% sulfuric acid and 30% hydrogen peroxide with a volume ratio of 2-4:1 is utilized to remove the organic residues at a temperature more than 100 degree Celsius. Such compound is referred to as a “Piranha Etchant” due to its good performance of removing organics. However, since some water is formed as a by-product in the use of the hydrogen peroxide, the etchant may be diluted in a short time if too much hydrogen peroxide is used, which leads to the lower cleaning efficiency. To be specific, the sulfuric acid transfers the organic residues on the wafer surface into the carbon atoms, the hydrogen peroxide is decomposed into oxygen atoms and water, the oxygen atoms and carbon atoms combine to form carbon dioxide, the water will dilute the sulfuric acid quickly so that the chemical cleaning effect will be reduced. Therefore, excessive hydrogen peroxide added in the treatment tanks may cause extremely serious results. Prior arts attempts to clean the organic residues using the Piranha Etchant by the steps as follows. At first, the sulfuric acid is poured into the treatment tank and heated to the required temperature. Then, the hydrogen peroxide is introduced and the wafer to be cleaned is placed into the treatment tank immediately thereafter. The hydrogen peroxide starts to be decomposed into oxygen atoms. The hydrogen peroxide is introduced into the treatment tank before the wafer being placed, relatively sufficient oxygen atoms can be decomposed to remove the carbon atoms transferred from the organics in the form of carbon dioxides. However, the water content can be relatively increased in the reaction between the hydrogen peroxide and the sulfuric acid, which dilutes the sulfuric acid, and the cleaning process has to be stopped in about ten minutes.

During the cleaning process mentioned above, the reaction between the hydrogen peroxide and the sulfuric acid proceeds according to the equation:

H₂O₂+H₂SO₄ [symbol] H₂SO₅+H₂O (1)

According to the published reports, when using the Piranha Etchant in the single wafer cleaning apparatus, the hydrogen peroxide at the room temperature should be mixed with the sulfuric acid at 120 to 150 degree Celsius so as to be effective. Since the mixing reaction (1) is an exothermic reaction, the compounds will reach a temperature of 200 degree Celsius and the etchant resist film of the organic residues can be peeled off the wafer surface in 60 to 90 seconds. However, the materials of the cleaning apparatus may also suffer from a great pressure under such high temperature. In addition, under such high temperature, the silicon nitride layer which protects the gate electrode on the wafer may be broken along the silicon lattice structure and exposed around the gate electrode thus to be etched as well. Moreover, the etchant just been mixed has to be replaced soon due to the short effective cleaning time and the high concentration of the water, causing a high etchant consumption. On the other hand, the carbon dioxide generated from the reaction of the carbon atoms and the oxide atoms decomposed from the hydrogen peroxide will escape from the treatment tank, leaving sticky liquids attached on the wafer surface. As a result, it is indispensable to wash the sticky liquids on the wafer surface by deionized water at 70 degree Celsius before rinsing the wafer by a SCl solution. Although the Piranha Etchant can remove the organic residues with high efficiency, it is incapable of removing the inorganic contaminants such as heavy metal.

### SUMMARY OF THE INVENTION

Accordingly, one objective of the present invention is to provide an etchant, a preparation method of the etchant as well as a method of using the etchant.

These and other objectives are met by the present invention, which in one aspect can be an etchant being a reaction product of sulfuric acid and ammonium persulfate, wherein the concentration of the ammonium persulfate is 1˜25%.

Preferably, the concentration of the ammonium persulfate is 5˜10%.

Wherein, the concentration of the sulfuric acid is 97˜99%. The ammonium persulfate is chemically pure or analytically pure.

Another aspect can be a preparation method of the etchant mentioned above. The preparation method comprises adding the ammonium persulfate into the sulfuric acid at a temperature of 100 to 200 degree Celsius and stirring until the ammonium persulfate is dissolved. When the ammonium persulfate is added into the hot sulfuric acid, HO—O—(SO₂)—(SO₂)—O—OH (H₂S₂O₈, persulphuric acid) is formed. The sulfuric acid is poured into the treatment tank made of quartz at 120 degree Celsius, when the ammonium persulfate powder added therein accounts for 5˜10% by weight of the mixture of the sulfuric acid and the ammonium persulfate, it will be dissolved in the sulfuric acid though a slow stir. If the content of the ammonium persulfate exceeds 25%, a rapid stir is needed.

A reaction between the sulfuric acid and the ammonium persulfate proceeds according to the equation:

(NH₄)S₂O₈+H₂SO₄→(NH₄)SO₄+H₂S₂O₈ (2)

Preferably, the ammonium persulfate is added into the sulfuric acid at 110 to 130 degree Celsius and dissolved by stirring.

Another aspect can be a method of using the etchant mentioned above to clean a wafer or photomask. The method comprises immersing the wafer or the photomask into the etchant for 5 to 20 minutes and taking out the wafer or photomask therefrom. When the wafer or photomask is processed by the etchant, the persulphuric acid is reacted with the organic residues on the wafer, which is represented as (CHO)ₓ, to form CO₂, H₂O and H₂SO₄, the reaction proceeds according to the equation:

H₂S₂O₈+(CHO)ₓ→xCO₂+xH₂O+H₂SO₄ (3)

The ammonium persulfate mixed in the sulfuric acid is stable and is reactive to generate persulphuric acid instead of large amount of water, and the generated persulphuric acid will react with the organics to further produce the sulfuric acid, thereby maintaining the concentration of the sulfuric acid for a long time. In the comparison of the conventional Piranha Etchant using hydrogen peroxide, since the hydrogen peroxide is unstable and is easy to be decomposed into water, the water concentration of the etchant will increase rapidly which leads to a lower solution concentration and even the failure of the etchant.

It is noted that, the etchant of the present invention should be used carefully during the cleaning process. Staffs are required to wear goggles, face masks and gloves when using the sulfuric acid, the ammonium persulfate and compounds thereof or working near.

Wherein, when the wafer or photomask to be cleaned is immersed into the etchant, the temperature of the etchant is 100 to 200 degree Celsius which will not be increased after the wafer or photomask being immersed as the reaction therebetween is not an exothermic reaction.

Wherein, the wafer or photomask to be cleaned is rinsed by cleaning liquids and deionized water before being immersed into the etchant. The temperature of the cleaning liquids is 58 to 65 degree Celsius; the temperature of the deionized water is 68 to 72 degree Celsius.

Wherein, after being removed from the etchant, the wafer or photomask is cleaned by a SCl solution at a temperature of 58 to 65 degree Celsius and deionized water at a temperature of 68 to 72 degree Celsius subsequently followed by a baking process.

According to the present invention, the ammonium persulfate is added into the sulfuric acid at a temperature of 100 to 200 degree Celsius to replace the conventional hydrogen peroxide. The ammonium persulfate in powder form will simplify the operation.

By using the etchant of the present invention, since sulfuric acid is formed as a by-product in the reaction rather than water, the etchant will not be diluted even being used for several times, so that the production cost is reduced.

Furthermore, since the sulfuric acid is formed as a by-product of the persulphuric acid during the cleaning process, excessive ammonium persulfate will not reduce the effectiveness of the etchant. The ammonium persulfate in the sulfuric acid can be at a concentration of 1% to 25%, so as to be used for cleaning the wafer as well as the photomask.

### DETAILED DESCRIPTION OF THE EMBODIMENTS

The etchant, the preparation of the etchant and the method of using the etchant of the presently preferred embodiments are discussed in further details hereinafter with respect the embodiments. However, the embodiments described herein are not the only applications or uses contemplated for the invention. The specific embodiments discussed are merely illustrative of specific ways to make and use the invention, and do not limit the scope of the invention or the appended claims.

The ammonium persulfate used in the following embodiments is marketed by BASF, FMC Chemicals, and is chemical pure.

### First Embodiment

The wafer to be cleaned is firstly rinsed by the SCl solution at 60 degree Celsius and then rinsed by the deionized water at 70 degree Celsius, and baked.

The sulfuric acid at a concentration of 98% is filled up in the treatment tank made of quartz and heated to 120 degree Celsius. Afterwards, the ammonium persulfate powder is added at this temperature slowly and stirred to dissolve. The ammonium persulfate powder is 7% by weight of the mixture of the sulfuric acid and the ammonium persulfate. Then the wafer is immersed into the treatment tank for 10 minutes.

After that, the wafer is removed out of the treatment tank, rinsed by the SCl solution at 60 degree Celsius and the deionized water at 70 degree Celsius, and baked by the IPA vapor.

The solution in the treatment tank will be changed into red or purple when the ammonium persulfate is consumed to be insufficient. Therefore, the consumption of the ammonium persulfate can be determined according to the color of the solution. The service life of the solution depends on the quantity of the wafers or photomasks to be cleaned. The more the wafers or photomasks are to be cleaned, the quicker the solution will fail. If the quantity of the wafers or photomasks to be cleaned is small, the solution can be used for a longer time. In the embodiment, the solution should be replaced after being prepared at an original proportion for about 4 hours, which means the etchant can be used for 4 hours.

As a result, the cleanliness of the processed wafer reaches the SEMI specification requirements.

### Second Embodiment

The wafer to be cleaned is firstly rinsed by the SCl solution at 60 degree Celsius and then rinsed by the deionized water at 70 degree Celsius, and baked.

The sulfuric acid at a concentration of 98% is filled up in the treatment tank made of quartz and heated to 130 degree Celsius. Afterwards, the ammonium persulfate powder is added at this temperature slowly and stirred to dissolve. The ammonium persulfate powder is 10% by weight of the mixture of the sulfuric acid and the ammonium persulfate. Then the wafer is immersed into the treatment tank for 8 minutes.

After that, the wafer is removed out of the treatment tank, rinsed by the SCl solution at 60 degree Celsius and the deionized water at 70 degree Celsius, and baked by the IPA vapor.

As a result, the cleanliness of the processed wafer reaches the SEMI specification requirements.

### Third Embodiment

The wafer to be cleaned is firstly rinsed by the SCl solution at 62 degree Celsius and then rinsed by the deionized water at 72 degree Celsius, and baked.

The sulfuric acid at a concentration of 98% is filled up in the treatment tank made of quartz and heated to 110 degree Celsius. Afterwards, the ammonium persulfate powder is added at this temperature slowly and stirred to dissolve. The ammonium persulfate powder is 5% by weight of the mixture of the sulfuric acid and the ammonium persulfate. Then the wafer is immersed into the treatment tank for 20 minutes.

After that, the wafer is removed out of the treatment tank, rinsed by the SCl solution at 60 degree Celsius and the deionized water at 68 degree Celsius, and baked by the IPA vapor.

As a result, the cleanliness of the processed wafer reaches the SEMI specification requirements.

### Fourth Embodiment

The sulfuric acid at a concentration of 98% is filled up in the treatment tank made of quartz and heated to 150 degree Celsius. Afterwards, the ammonium persulfate powders are added at this temperature slowly, and are stirred with high speed until being dissolved. The ammonium persulfate powders are 25% by weight of the mixture of the sulfuric acid and the ammonium persulfate. The other processing steps are almost the same as those in the first embodiment, which are omitted herein.

As a result, the cleanliness of the processed wafer reaches the SEMI specification requirements.

### Fifth Embodiment

Since the photomask is a component used in the lithography of the wafer which may also be contaminated by the organics, it can be cleaned by the same cleaning process as the wafer. The cleaning process of the photomask is almost the same as that described in the first embodiment, which is omitted herein.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. An etchant, wherein the etchant is a reaction product of sulfuric acid and ammonium persulfate, and the concentration of the ammonium persulfate added during the reaction is 1˜25%.

2. The etchant according to claim 1, wherein the concentration of the ammonium persulfate is 5˜10%.

3. The etchant according to claim 1, wherein the concentration of the sulfuric acid is 97˜99%.

4. A preparation method of an etchant, wherein the etchant is a reaction product of sulfuric acid and ammonium persulfate and the concentration of the ammonium persulfate is 1˜25%, the preparation method comprising:
Adding the ammonium persulfate into the sulfuric acid at a temperature of 100 to 200 degree Celsius and stirring to dissolve the ammonium persulfate.

5. The method according to claim 4, wherein the ammonium persulfate is added into the sulfuric acid at a temperature of 110 to 130 degree Celsius and is stirred to dissolve.

6. (canceled)

7. A method of cleaning a wafer or photomask using an etchant, wherein the etchant is a reaction product of sulfuric acid and ammonium persulfate and the concentration of the ammonium persulfate is 1˜25%, the method comprising:
immersing the wafer or photomask into the etchant for 5 to 20 minutes, and taking out the wafer or photomask thereafter.

8. The method according to claim 7, wherein the wafer or photomask is cleaned by a cleaning solution and deionized water before being immersed into the etchant, the cleaning solution is at a temperature of 58 to 65 degree Celsius, the deionized water is at a temperature of 68 to 72 degree Celsius.

9. The method according to claim 7, wherein after being taken out of the etchant, the wafer or photomask is cleaned by the cleaning solution at a temperature of 58 to 65 degree Celsius and deionized water at a temperature of 68 to 72 degree Celsius, and baked.

10. The method according to claim 7, wherein the concentration of the ammonium persulfate is 5˜10%.

11. The method according to claim 7, wherein the concentration of the sulfuric acid is 97˜99%.

12. The method according to claim 4, wherein the concentration of the ammonium persulfate is 5˜10%.

13. The method according to claim 4, wherein the concentration of the sulfuric acid is 97˜99%.
